(19) United States
(12) Patent Application Publication
(10) Pub. No.: US 2023/0348761 A1
(43) Pub. Date: Nov. 2, 2023

(54) GLASS PRODUCT, METHOD OF APPLYING CONNECTOR TO GLAZING, AND CONNECTOR

(71) Applicant: CARLEX GLASS AMERICA, LLC, Nashville, TN (US)

(72) Inventors: Wladislaw BRONSTEIN, Trier (DE); Olivier FARREYROL, Wasserbillig (LU); Jacob Daniel RIGELMAN,, Garrett, IN (US)

(21) Appl. No.: 18/014,086

(22) PCT Filed: Jul. 1, 2021
(86) PCT No.: PCT/US2021/040129

§ 371 Date: Dec. 30, 2022

Related U.S. Application Data
(60) Provisional application No. 63/047,660, filed on Jul. 2, 2020.
(60) Provisional application No. 63/047,577, filed on Jul. 2, 2020.
(60) Provisional application No. 63/047,610, filed on Jul. 2, 2020.
(60) Provisional application No. 63/047,626, filed on Jul. 2, 2020.

(51) Int. Cl. C09J 9/02; H01L 21/683

(52) U.S. Cl. CPC C09J 9/02; H01L 21/6836; C09J 2203/326

(57) ABSTRACT

A glass product includes a glazing having a connectable material with a connecting surface on the glazing, a connector including a housing, and a connector plate within the housing, and a conductive material within the housing; at least part of the conductive material being positioned between the connector plate and the connecting surface.

### CROSS REFERENCE TO RELATED APPLICATIONS

This application claims priority to U.S. Provisional Application No. 63/047,577, filed on Jul. 2, 2020, entitled “Electrical Connector,” U.S. Provisional Application No. 63/047,610, filed on Jul. 2, 2020, entitled “Electrical Connector,” U.S. Provisional Application No. 63/047,626, filed on Jul. 2, 2020, entitled “Electrical Connector,” and U.S. Provisional Application No. 63/047,660, filed on Jul. 2, 2020, entitled “Electrical Connector,” the entire contents of which are incorporated by reference herein in their entireties.

### TECHNICAL FIELD

The present disclosure generally relates to glass products, electrical connectors, and methods of applying such electrical connectors to a glazing.

### BACKGROUND

Traditionally, electrical connectors have been soldered to electrically conductive materials in automotive glass via lead-containing solder. However, new directives have instituted use of lead-free solders, which have proven difficult, as mechanical stresses at the connectors lead to cracks in an underlying glass. U.S. Pat. No. 9,520,665 (the '665 patent) discloses an electrical connector attached to a glass plate with a conductive rubber at least partially surrounded by a thermosetting adhesive on the underside of the connector. The process described in the '665 patent uses heat and pressure from an autoclaving process during glass lamination to adhere the connector to glass.

### SUMMARY OF THE DISCLOSURE

Disclosed herein is a glass product including a glazing having a connectable material with a connecting surface thereon, a connector including a housing, a connector plate within the housing, and an extension which extends from the connector plate through the housing, and a conductive material within the housing, wherein at least part of the conductive material is positioned between the connector plate and the connectable material.

In an embodiment of the present disclosure, the extension may be a wire connection.

In another embodiment, the glass product may further include a non-conductive material within the housing. The connector may include at least one spring positioned between the housing and the connector plate. The at least one spring may be evenly distributed across the connector plate. The connector may include an adhesive on a bottom surface of the housing. The adhesive may be pressure sensitive adhesive or ultraviolet light curable adhesive.

In another aspect of the present disclosure, a method of applying a connector to a glazing may include placing the connector including a housing and a connector plate within the housing over a connecting surface on the glazing; filling the housing with a conductive material through an opening in the housing; and sealing the opening and a bottom edge of the housing.

In an embodiment of the present disclosure, it may be that there is no air pocket in the housing after sealing. The connector plate may be held in position in relation to the housing prior to placing the connector with a clip. The clip may be removed prior to sealing the opening. A housing interior width may be larger than a connector plate width. The bottom edge of the housing may be sealed before filling the housing.

In another embodiment, the method may further include filling the housing with a non-conductive material through the opening in the housing after the filling the housing with the conductive material. The connector may include at least one spring positioned between the housing and the connector plate. The housing may include adhesive on a bottom surface of the housing.

In another aspect of the present disclosure, a method of applying a connector to a glazing may include positioning a conductive material on a connecting surface on the glazing; and positioning the connector including a housing and a connector plate within the housing over the conductive material. The housing may include an adhesive on a bottom surface of the housing. The adhesive may be a pressure sensitive adhesive or an ultraviolet light curable adhesive.

In another embodiment, the method may further include filling the housing with a non-conductive material through an opening in the housing after the positioning the connector over the conductive material. The connector may include at least one spring positioned between the housing and the connector plate.

In another aspect of the present disclosure, a connector may include a housing; a connector plate within the housing; an extension which extends from the connector plate through the housing; a conductive material within the housing; and a film across a bottom of the housing, wherein the film encloses a space within the housing.

In an embodiment of the present disclosure, the extension may be a wire connection. The connector may further include a clip on the extension, wherein the clip holds the connector plate in place in relation to the housing. The connector may further include an adhesive on a bottom surface of the housing, wherein the film across the bottom of the housing covers the adhesive on the bottom surface of the housing. The adhesive may be pressure sensitive adhesive or ultraviolet light curable adhesive.

In another embodiment, the connector may further include at least one spring within the housing, wherein the at least one spring is positioned between the connector plate and the housing.

In another aspect of the present disclosure, a method of applying the connector of the present disclosure to a glazing includes selecting the connector of the present disclosure, removing the film from the bottom of the connector; and placing the connector over a connecting surface on the glazing.

In an embodiment of the present disclosure, the method may further include curing an adhesive on the bottom surface of the connector. The adhesive may be provided on a bottom surface of the housing.

### BRIEF DESCRIPTION OF THE DRAWINGS

The accompanying drawings, which are incorporated into and constitute a part of this specification, illustrate one or more aspects of the present disclosure and, together with the detailed description, serve to explain their principles and implementations.

FIG. 1 is a cross section showing a connector, according to an embodiment of the present disclosure;

FIG. 2 is a cross section showing a glass product, according to an embodiment of the present disclosure;

FIG. 3 is a cross section showing a glass product, according to an embodiment of the present disclosure;

FIG. 4 is a cross section showing a method of applying a connector to a glazing, according to an embodiment of the present disclosure;

FIG. 5 is a cross section showing a method of applying a connector to a glazing, according to an embodiment of the present disclosure;

FIG. 6 is a cross section showing a glass product, according to an embodiment of the present disclosure;

FIG. 7 is a cross section showing a method of applying a connector to a glazing, according to an embodiment of the present disclosure;

FIG. 8 is a cross section showing a connector, according to an embodiment of the present disclosure;

FIG. 9 is a cross section showing a glass product, according to an embodiment of the present disclosure;

FIG. 10 is a cross section showing a glass product, according to an embodiment of the present disclosure;

FIG. 11 is a cross section showing a method of applying a connector to a glazing, according to an embodiment of the present disclosure;

FIG. 12 is a cross section showing a method of applying a connector to a glazing, according to an embodiment of the present disclosure;

FIG. 13 is a cross section showing a connector, according to an embodiment of the present disclosure;

FIG. 14 is a cross section showing a glass product, according to an embodiment of the present disclosure;

FIG. 15 is a cross section showing a connector, according to an embodiment of the present disclosure;

FIG. 16 is a cross section showing a connector according to an embodiment of the present disclosure;

FIG. 17 is a cross section showing a glass product, according to an embodiment of the present disclosure; and

FIG. 18 is a cross section showing a glass product, according to an embodiment of the present disclosure.

### DETAILED DESCRIPTION

In the following description, for purposes of explanation, specific details are set forth in order to promote a thorough understanding of one or more aspects of the disclosure. It may be evident in some or all instances, however, that many aspects described below can be practiced without adopting the specific design details described below.

Disclosed herein is a glass product including a glazing having a connectable material with a connecting surface thereon, a connector including a housing, a connector plate within the housing, and a conductive material within the housing; at least part of the conductive material being positioned between the connector plate and the connecting surface.

Glass products, including automotive glass products, may include glazings and connectors where power is to be supplied to the glazing or an element of the glazing. Particularly, a coating or print may be powered, for example, to be heated. Printed silver, for example, may be located across a glazing, such as heating lines across a rear window, or in a localized area, such as wiper park heating lines. Coatings or printings may require a connector to provide power from an electrical source to heat the coating or print. Antennas, likewise, may require a connector to connect to a receiver. A connector may be attached to an outer surface of the glazing, such that in a laminated glazing, the connector may be attached without regard for timing of an autoclave process. In some glazings, a connectable material may be provided on a glazing interior surface and include a glass cutout which may allow for a connector to be attached after the glazing is laminated. Further, some glazings may not be laminated. For example, a rear window may be a tempered glass substrate that is not laminated. Among other things, a method of applying a connector, as disclosed herein, may advantageously work for both laminated and non-laminated glazings.

An automotive glazing may include a coating or print material which may be electrically connectable. Coatings may, for example, include metals, such as silver, or conductive oxides. In some embodiments, the electrically connectable materials may be printed onto the glazing, including by screen printing. For example, silver, or silver alloy, material may be screen printed onto a glass substrate, such as lines across a rear window for heating and melting snow and ice on the window. Printed electrically connectable materials may further be provided in an area of a windshield or rear window where a wiper may sit in an off position. Such a “wiper park” may include a printed silver which is heatable by connection to a power supply. A printed connectable material may be any suitable pattern to provide adequate heating or power to a desired area or areas and may include an area printed for connecting to an electrical connector. In some embodiments, the glazing may include an opaque print at a periphery and/or around an accessory, such as a camera or sensor, and the connectable material may be printed on the glass and/or an opaque print. The connector may be applied to connect to a power source or a signal receiver, such as for an antenna. A connectable silver print may include an area which is to be connected to a connector. The connectable material may be electrically connected to a connector applied thereto at a connecting surface.

A connector may provide a conductive attachment between a power source or receiver and a connectable material. Particularly, a connectable material formed on a glazing, including an antenna, may include a busbar or other connecting surface. A connecting surface may include a busbar or another surface for attaching a connector to a connectable material. A busbar may be any suitable form, such as a silver-containing material and/or a metallic tape, such as a copper tape. A copper tape may be positioned over other connectable materials and form a suitable surface for attaching a connector. A busbar may be formed on some glazings as a silver printed busbar. A busbar may be formed to connect a coating, a printed silver layer, an antenna, or any other suitable material to a connector. In some glazings, the busbar may be printed on a black frit on a glass substrate.

In certain embodiments described herein, a connector may be provided which includes a housing and a connector plate within the housing. A conductive material may be used between a connecting surface and the connector plate to properly connect the materials and provide a suitable contact between the materials. The connector plate may be surrounded by the conductive material to ensure a suitable connection between the materials in some embodiments. In other embodiments, the conductive material may not cover a top of the connector plate. The connector plate may have an extension which may extend out of the housing. The extension may be used to connect the connector plate to a power source or a receiver and may thus be formed of a conductive material. The extension may be formed as a single piece with the connector plate or may be attached to the connector plate. Where the extension is attached to the connector plate, the extension may be attached by any suitable means, including welding, soldering, riveting, crimping, etc. In some embodiments, the extension may extend from the connector plate through an opening in the housing. The opening may be sealed around the extension. The extension may be in the form of a wire. In particular embodiments, a wire extension may be attached to the connector plate via a crimp connection where the wire is crimped to the connector plate.

The glass product may further include a clip on the extension. In order to maintain the connector plate in the housing prior to assembly on a glazing, the connector plate may be held to the housing with a clip. The clip may hold the connector plate in place in relation to the housing. For example, a clip may be positioned on a connector plate extension such that the connector plate may be held in place relative to the housing. The clip may be removable such that the connector plate is released when the clip is removed. Preferably, the clip may be removed after the housing is filled with a conductive material. In some embodiments, the connector extension may be formed with the connector plate and the housing in a fixed relationship, such that a clip may not be required for all connectors used herein.

A suitable housing material may be a nonconductive material, including a plastic such as polycarbonate. The housing may have sufficient strength such that the housing may not change in shape under pressure of conductive material filled therein. The connector plate within the housing may be a material having suitable conductivity with a conductive strength such that a power source may be adequately attached thereto and provide sufficient conductivity to transfer electrical voltage from the power source to the connectable material or to provide a signal to a receiver. For example, the connector plate may include copper, iron, aluminum, nickel, or alloys including such metals. An extension on the connector plate may be electrically conductive such that the extension may electrically connect the connector plate to a power source or a receiver. The extension may, in some embodiments, be the same material as the connector plate. In some embodiments, the extension may be a conductive wire, which may include a nonconductive insulative coating around such a wire. In certain embodiments, the connector plate may have a shape matching the glazing surface shape. A matching shape between the glazing and connector plate may reduce inhomogeneities of thickness of the conductive material, which may improve conductivity and reduce a risk of creating a hot spot. Sharp edges of the connector plate which may contact a glazing may preferably be avoided. Thus, in some preferable embodiments the connector plate may have smooth edges.

Where the connector described herein is applied to a glazing, a conductive material may be positioned between the connector plate and a connecting surface on the glazing. The conductive material may be any suitable material, including having a suitable electrical resistance. Particularly, the conductive material may include: a metal, such as silver, copper, or aluminum; metal-containing material, such as an alloy; or a carbon material such as graphite or carbon nanotube. The conductive material may be applied in a form of a paste. For example, a silver paste may be usable as a conductive material. A medium may contain 2-(2-ethoxyethoxy)ethyl acetate and other components similar to automotive silver paste. A concentration of silver in the paste may range from 50 to 90 wt %, preferably 80 to 90 wt %, even more preferably 85 to 90 wt %. Viscosity may be 5000-100000 cP (or mPa·s) at 25° C., preferably 9000-35000 cP (or mPa·s) at 25° C., measured by a rheometer, such as Brookfield DVIII, SC4-14/6R at 20 rpm. Sheet resistivity of a silver paste may be 1-10 mΩ/sq at 25 μm, preferably 7-8 mΩ/sq at 25 μm. A solder paste may be usable as a conductive material. It may contain metallic solder alloy powder like SAC alloy [tin-silver-copper] with flux type Ro10, resin flux. This may be more cost effective than silver paste. The particle size of SAC powder in the flux may be 1-100 μm, preferably 15 to 45 μm. Metal content in the solder paste may be 50 to 90 wt %, preferably 85 to 90 wt %. Viscosity may be 10000-1000000 cP (mPa·s), preferably 100000-900000 cP (mPa·s). In some embodiments, the conductive material may be compressible such that, under pressure, the conductive material may compress and form a stronger electrical connection between an underlying connecting surface and the connector plate. Pressure may be applied to the conductive material by filling the housing with the material and providing a seal such that the conductive material may not be released from the housing. Enough conductive material may be added to the housing such that it is in a somewhat compressed state within the housing. The conductive material may fill around a connector plate within the housing such that a bottom and top of the connector plate may be in contact with the conductive material.

The connector may include an adhesive on a bottom surface of the housing. The adhesive may be a pressure sensitive adhesive, a temperature curable adhesive, or an ultraviolet light curable adhesive. The housing may be adhered to the glazing, particularly at a connecting surface on the glazing. An adhesive sealing material may be used around and/or under a bottom edge of the housing to adhere the housing to the glazing and to seal the edge between the materials. In some embodiments, an adhesive may be provided on the bottom edge of the housing and a release liner may cover the adhesive prior to installing the connector. The release liner may be removed before the connector housing is positioned on a glazing. Where the adhesive is provided on the bottom of the housing, as the housing is positioned on the glazing, the adhesive may partially spill out from underneath the housing so that the adhesive is under the housing and at an edge of the housing where the housing meets the glazing. The shape of the housing bottom surface may be designed to allow spilling out outside of the housing rather than inside of the housing. For example, the bottom surface may be higher on an outside edge compared to an inside edge of the housing bottom surface. Some housings may include a bottom surface that has a recess for placement of the adhesive. The shape of the housing bottom may be selected, at least in part, by the viscosity of the adhesive. In some embodiments, adhesives may be applied at each of the bottom of the housing and around an edge of the housing. An adhesive applied to the bottom of the housing may be the same or different from an adhesive applied around a bottom edge of the housing. Applying an adhesive around the edge of the housing where it meets the glazing may improve strength against peeling. The spilling out of adhesive or additional adhesive may further improve protection against moisture or chemicals for the materials within the housing. The seal may have suitable mechanical strength to maintain the housing in position on the glazing. The adhesive may preferably be an ultraviolet light (UV) curable adhesive, a temperature curable adhesive, or a pressure sensitive adhesive. Adhesive may also include multi-component adhesives and others. An adhesive tape may be used as such a seal around the housing edge or on a bottom surface of the housing edge. Such a tape may be a double sided adhesive tape. In some embodiments, the housing material may be transparent to UV light which may be used for curing an adhesive under the housing. The adhesive may be, for example, polyurethane resin, epoxy resin, methacrylic resin or silicone resin.

Where the housing is provided having an opening, the opening though the housing may further be sealed such that conductive material within the housing is not exposed to ambient conditions. The seals may prevent moisture and chemicals from reaching conductive material within the housing. Preferably, the conductive material completely fills the housing such that there are no air pockets in the sealed housing. The housing interior may have rounded surfaces without sharp corners to minimize possibility of air pockets within the housing. The conductive material may be filled through the opening in the housing. A second opening may be provided in the housing as a vent to allow for air to leave the housing interior as conductive material is administered into the housing. The opening through the housing and any vent opening may be sealed after the conductive material is positioned within the housing and the connector plate is in position, which may be when the housing is positioned and adhered to the connecting surface on a glazing. The seal may be polyurethane resin, epoxy resin, methacrylic resin or silicone resin and may be same or different from a seal positioned below or at the edge of the housing.

In another embodiment, the glass product may further include a non-conductive material within the housing. A non-conductive material may be provided within the housing to fill the space within the housing which may be left if the conductive material does not fill the entire space. The non-conductive material may apply pressure to the conductive material where the housing is partially filled with conductive material and then the rest of the housing may be filled with the non-conductive material, such that the non-conductive material may fill a space above the conductive material, relative to a connecting surface. Preferably, the non-conductive material may expand within the housing. The expansion may induce pressure against the connector plate, towards the connecting surface, as the non-conductive material is positioned above the connector plate. An expanding non-conductive material may include, for example, a polyurethane foam. A seal may be formed on a housing opening, through which the non-conductive material is administered, directly after the non-conductive material is placed in the housing. In some embodiments, the non-conductive material may act as a sealing material. A vent opening may further be provided in the housing where non-conductive material is administered through an opening and the vent opening may also be sealed directly after non-conductive material is placed in the housing. The conductive material may fill around a connector plate within the housing such that a bottom and top of the connector plate may be in contact with the conductive material. In some embodiments, the connector plate may be partially or entirely covered on a top surface by the non-conductive material.

Preferably, the conductive material and the non-conductive material completely fill the housing such that there are no air pockets in the sealed housing. The conductive material may include metal particles which may be costly as compared to non-conductive materials free of such conductive particles. Thus, it may be preferable, in some embodiments, to fill the housing, above a conductive material, with a non-conductive material. Particularly, the non-conductive material may be a resin, metal oxide, or elastomer, such as a paste or particles. The non-conductive material may include polyurethane resin or epoxy resin. The non-conductive material may be thermoplastic. Preferably, the non-conductive material may not mix with the conductive material within the housing, such that conductive particles in the conductive material may not migrate to the non-conductive material. It may be preferable to keep the materials separate, such that the conductivity of the conductive material is not reduced by such migration. The non-conductive material may further function as a seal at an opening of the housing. Where the non-conductive material is a seal, an additional seal material may not be required at the housing opening.

In another embodiment of the glass product, the connector may include at least one spring positioned between the housing and the connector plate. The at least one spring may be evenly distributed across the connector plate. In certain embodiments described herein, a connector may be provided which includes a housing, a connector plate within the housing, and a spring positioned between the housing and the connector plate. There may be more than one spring positioned between the housing and the connector plate. The springs may be positioned such that a lower surface of the connector plate maintains a substantially parallel surface with an underlying glazing surface. In some exemplary embodiments, the springs may be distributed evenly across the connector plate. For example, a connector plate may be symmetrical in relation to the springs attached thereto. The connector plate may preferably be positioned against the conductive material with pressure from the springs to ensure a suitable connection between the materials. The springs between the connector plate and the housing may push against the connector plate and compress conductive material under the connector plate. The pressure from such springs may compress the underlying conductive material and provide a suitable connection for a power source or receiver. The compression in the springs may be chosen based on the height and size of the connector plate to ensure suitable compression of the conductive material. In some embodiments, the connector plate may be held above a position it will have when applied to a glazing. In such a connector, the spring(s) may be more compressed when held with a clip or other means than when the connector is attached to a glazing. The housing may have sufficient strength that the housing may not change in shape under pressure of the springs between the connector plate and the housing. The seal may have suitable mechanical strength to withstand pressure from springs in a housing and maintain the housing on the glazing.

The extension may preferably extend out of the housing either through a ceiling of the housing or through a side wall of the housing. The extension may extend out of the housing through an opening used for filling the housing with conductive material and/or non-conductive material, a vent opening, or through a separate point in the housing. The housing may have an opening at a side face of the housing, instead of at the top face of the housing. An extension may extend from the connector plate through the opening at the side face of the housing. The opening at the side face of the housing may be sealed closed as described above. Such a configuration may be used in another embodiment of the glass product and connector disclosed herein.

In another embodiment of the glass product, the glass product may include a connector on a glazing having a plurality of connecting surfaces thereon. The connector may have a multiple-compartment housing having at least two independent compartments, each of which includes a connector plate and a conductive material. Each compartment is electrically isolated from other compartments such that the connector plates remain electrically isolated from each other. The housing material may be non-conductive such that the compartments may remain electrically isolated from each other. Where the housing separates the compartments, a seal, which may include adhesive between the compartments may not allow for the migration of conductive material such that the seal retains electrically isolated compartments. Each connector plate may have an extension as described above and may be electrically connected to an underlying connecting surface. A conductive material may be positioned at least partially between the connector plate and the connecting surface. In some embodiments, a non-conductive material may further be provided within the housing to fill the space in each compartment of the housing. In some embodiments, the connector may include at least one spring, as described above, positioned between the connector plate and the interior of the housing of each compartment.

Further disclosed herein is a method of applying a connector to a glazing including placing the connector, including a housing and a connector plate within the housing, over a connecting surface on the glazing; filling the housing with a conductive material through an opening in the housing; and sealing the opening and a bottom edge of the housing.

Connectors disclosed herein may be assembled on a glazing by positioning the housing on a glazing and filling, through an opening on the housing, the housing interior with a conductive material. Prior to placing the connector on a connecting surface, the connecting surface may be cleaned; for example, silver print may be burnished. There may be space in the housing between the housing and the connector plate through which the conductive material may flow around the connector plate, such that the conductive material may be between the connector plate and an underlying connecting surface on the glazing. Where the connector plate is releasable, it may be released when the housing is at least partially or fully filled. The housing may be filled with conductive material and sealed at the housing opening. Sealing the opening of the housing may include use of an ultraviolet light curable seal material. Further, the bottom edge of the housing may be sealed by adhesive. The bottom edge of the housing may be sealed before filling the housing. The housing may include adhesive on a bottom surface of the housing and sealing the bottom edge of the housing may include curing the adhesive on the bottom surface of the housing. Sealing the bottom edge of the housing may be completed prior to filling the housing with the conductive material. Preferably, it may be that there is no air pocket in the housing when the opening is sealed. A seal may fill some space at the top of the housing left which may be left after filling the housing with conductive material.

Where an opening having an extension therethrough in the housing is sealed, the seal may be formed around the extension. The extension may preferably extend through a seal, such that the extension may be connected to a power source or a receiver. The extension may be directly connected to a power source, a receiver, or a connector, such as a flex connector, may be attached to the connector for connecting to a power source or a receiver. The sealing material may have sufficient adhesion to a housing material and the extension material. The extension may have a nonconductive casing to which the seal may adhere. In some embodiments, the housing opening to be sealed may not include the extension therethrough, as the extension may extend through the housing in another position.

In some embodiments, the amount of conductive material in the housing may be sufficient to extend above the connector plate and may fill the housing. The housing interior may have a width greater than a width of the connector plate such that there is space for the conductive material to fill around the edges of the connector plate.

The connector plate may be held in position in relation to the housing with a clip or other means prior to placing the connector. The clip may be removed prior to sealing the opening.

The method may further include filling the housing with a non-conductive material through the opening in the housing after filling the housing with the conductive material. The non-conductive material may be administered through an opening in the housing which is sealed after the non-conductive material fills the housing. In some embodiments, the non-conductive material may expand to fill the housing and may apply pressure to the conductive material within the housing. In some embodiments, the extension may extend through the housing at a point different from the opening used for filling the housing with conductive and non-conductive materials.

In another embodiment of the method of applying a connector, the connector may include at least one spring positioned between the housing and the connector plate. When the connector plate is released, the spring(s) may expand and apply pressure against the connector plate. The pressure from such springs may compress the underlying conductive material and provide a suitable connection for a power source or receiver.

Disclosed herein is another method of applying a connector to a glazing including positioning a conductive material on a connecting surface on the glazing; and positioning the connector, including a housing and a connector plate within the housing, over the conductive material.

Connectors described herein may be applied to a glazing such that a conductive material is positioned between a connecting surface on the glazing and the connector plate. Prior to placing the connector on a connecting surface, the connecting surface may be cleaned; for example, silver print may be burnished. In some embodiments, a conductive material, such as a metallic paste or alloy, may be positioned in an area for connector attachment. The conductive material may be positioned over a connecting surface on the glazing in an amount to form a suitable connection with the connector plate. Preferably, the conductive material may be in an amount to completely cover the bottom surface of the connector plate. The electrical connector described herein may be placed over the conductive material such that the connector plate is aligned with a desired connection area on the glazing, particularly at the connecting surface. The connector housing may include a vent opening for removal of air as the connector is positioned. The vent opening may be sealed once the housing is in place over the conductive material. When the electrical connector is in place, a clip holding the connector plate in place may be removed, releasing the connector plate. In some embodiments, the connector extension may be formed with the connector plate and the housing in a fixed relationship, such that a clip may not be required for all connectors used herein. The housing edges may include an adhesive or a tape may be applied to the edges to maintain the housing in place. The housing may include an adhesive on a bottom surface of the housing. The adhesive may be a pressure sensitive adhesive, a temperature curable adhesive, or an ultraviolet light curable adhesive. In some embodiments, the amount of conductive material used may be sufficient to extend above the connector plate within the housing and may fill the housing. The housing interior may have a width greater than a width of the connector plate such that there is space for the conductive material to fill around the edges of the connector plate and may fill above the connector plate.

In another embodiment of the method of applying a connector, the method may further include filling the housing with a non-conductive material through the opening in the housing after the positioning the connector over the connecting surface. The non-conductive material may be administered through an opening in the housing which is sealed after the non-conductive material fills the housing. In some embodiments, the extension may extend through the housing at a point different from the opening used for filling the housing with the non-conductive material. Where the non-conductive material is provided through an opening a second vent opening may be provided through which air may pass out of the housing. The vent opening may be sealed after the non-conductive material is administer into the housing.

In another embodiment of the method of applying a connector, the connector may include at least one spring positioned between the housing and the connector plate. In some embodiments, the connector plate may be held so that the spring is in a compressed state while the connector is positioned over the conductive material and released when the housing is filled completely with conductive material. When the connector plate is released, the spring(s) may expand and apply pressure against the connector plate. The pressure from such springs may compress the underlying conductive material and provide a suitable connection for a power source or a receiver.

A further embodiment of the present disclosure includes a connector including a housing; a connector plate within the housing; a conductive material within the housing; and a film across a bottom of the housing, wherein the film encloses a space within the housing.

A conductive material may be provided within the housing. Particularly, the conductive material may fill the housing interior around a connector plate. The conductive material may fill a space above and below the connector plate within the housing. The conductive material may be kept within the housing with a releasable film, or liner. The liner may be removed from the housing prior to applying the connector to a glazing. In some embodiments, a non-releasable liner may be broken to release the conductive material within the housing such that the conductive material may form an electrical attachment between a connectable material and the connector plate. The liner may releasably attach to the housing edges, enclosing the conductive material in the housing interior. The liner may further cover an adhesive on the housing bottom surface. The conductive material may be any suitable material, including having a suitable electrical resistance, including those discussed above. Particularly, the conductive material may be a metal or metal containing material, such as a paste or an alloy. In some embodiments, the conductive material may be compressible such that, under pressure, the conductive material may compress and form a strong electrical connection between an underlying connectable material and the connector plate. When the film liner is removed from the housing, the housing may be applied to a glazing over a connectable material, such as a busbar. The conductive material within the housing may fill an area between the connector plate and the connecting surface when on a glazing. Prior to applying the connector, there may be conductive material within the housing between the connector plate and the releasable film liner.

The connector plate may include an extension which extends from the connector plate through the housing. The extension may be a wire connection. The connector may further include a clip on the extension, wherein the clip holds the connector plate in place in relation to the housing. The connector may further include an adhesive on a bottom surface of the housing, wherein the film across the bottom of the housing covers the adhesive on the bottom surface of the housing. The adhesive is pressure sensitive adhesive, temperature curable adhesive, or ultraviolet light curable adhesive. In another embodiment, the connector may further include at least one spring within the housing, wherein the at least one spring is positioned between the connector plate and the housing.

Disclosed herein is another method of applying the connector described above to a glazing including selecting the connector described above, removing the film from the bottom of the connector; and placing the connector over a connectable material on the glazing.

Connectors disclosed herein may be assembled on a glazing by removing the film from the bottom of the connector and placing the connector over a connecting surface on the glazing. The method may further include curing an adhesive on the bottom surface of the connector. The adhesive may be provided on a bottom surface of the housing. The adhesive may be a pressure sensitive adhesive, a temperature curable adhesive, or an ultraviolet light curable adhesive.

In some embodiments, the connector may be applied to a glazing prior to treatment in an autoclave. The height of such a connector may preferably be limited. An autoclave may have a controlled size for the inclusion of glazings to be autoclaved. Adding to the thickness of the glazings, including with materials positioned on the glazings, may reduce the number of glazings which may fit within an autoclave. Where the connector is applied to a glazing prior to an autoclave treatment, the connector may have a height of preferably 30 mm or less, more preferably 20 mm or less.

The connectors and methods disclosed herein may be used without the addition of heat to a glazing, particularly where the housing is attached to a glazing using a pressure sensitive adhesive or a UV curable adhesive. Without heat, some heat sensitive materials may be used in such connectors and the connection methods may avoid thermal damage to a glazing. Further, the connectors may be applied without the use of an autoclave, such that they may be used for laminated and nonlaminated glazings.

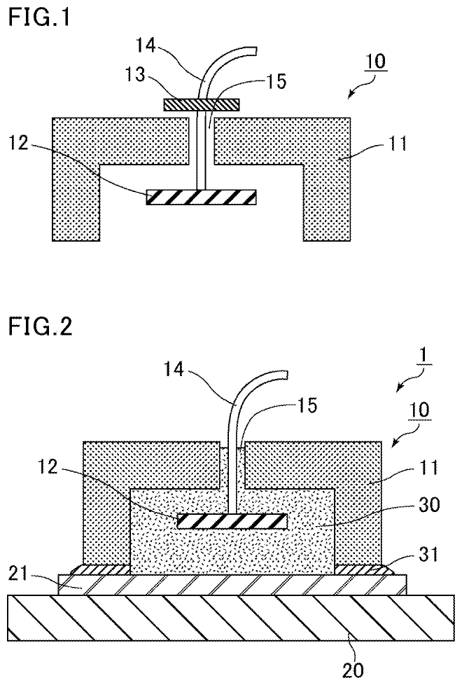

FIG. 1 illustrates a connector according to some embodiments disclosed herein. FIG. 1 illustrates a connector 10 having a housing 11 and a connector plate 12 within the housing 11. The connector plate 12 includes an extension 14 which extends from the connector plate 12 through an opening 15 in the housing 11. A clip 13 is attached to the extension 14 and holds the connector plate 12 in place in relation to the housing 11.

FIG. 2 illustrates a glass product according to an embodiment disclosed herein. A glass product 1 shown in FIG. 2 includes a connector 10 on a glazing 20 having a connecting surface 21 as a glazing busbar thereon. The housing 11 shown has been filled with a conductive material 30 and the clip 13 (see FIG. 1) removed from the extension 14. A seal 31 is shown at an edge of the housing 11. As shown, the seal 31 may spill out from under the housing 11 when applied to the connecting surface 21. The seal 31 may, in some embodiments, remain entirely on the bottom of the housing 11. The physical properties of the seal 31 and the application process may contribute to the final placement of the seal 31. The conductive material 30 within the housing 11 is positioned between the connector plate 12 and the connecting surface 21. The connector plate 12 is electrically connected to the underlying connecting surface 21 by the conductive material 30 therebetween. In some embodiments, the housing 11 may be sealed in place prior to filling the housing 11 with a conductive material 30. As shown in FIG. 2, the conductive material 30 may fill the entire housing 11, including below and above the connector plate 12. In some embodiments, the extension 14 may include an insulative coating.

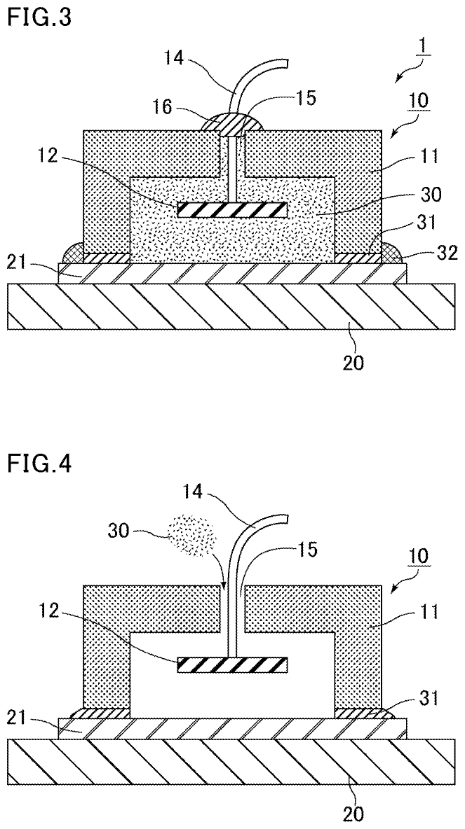

FIG. 3 illustrates a glass product according to an embodiment disclosed herein. FIG. 3 illustrates a connector 10 attached to a glazing 20 wherein the connector housing 11 is sealed closed. As shown, the housing interior may have no air pockets under the housing seal 16. The seal 16 is formed over a housing opening 15 and may be formed around an extension 14 which may pass through such an opening 15. The seal 16 may also extend partially into the housing 11 through the opening 15, as shown. In some embodiments, an additional seal 32 may be positioned at an edge of the housing 11 where it meets the connecting surface 21. The additional seal 32 may be applied when the housing 11 is positioned on the connecting surface 21 and may provide additional adhesion and chemical protection. Some embodiments may exclude the additional seal 32.

FIG. 4 illustrates one method of applying connector of the present disclosure. A connector 10 having a housing 11 and a connector plate 12 within the housing 11 is placed over a connecting surface 21 on a glazing 20. A conductive material 30 is filled in the housing 11 through an opening 15. A seal 16 (See FIG. 3) may further be formed over the housing opening 15. A bottom edge of the housing 11 may be also sealed. The seal 31 may spill out from under the housing 11.

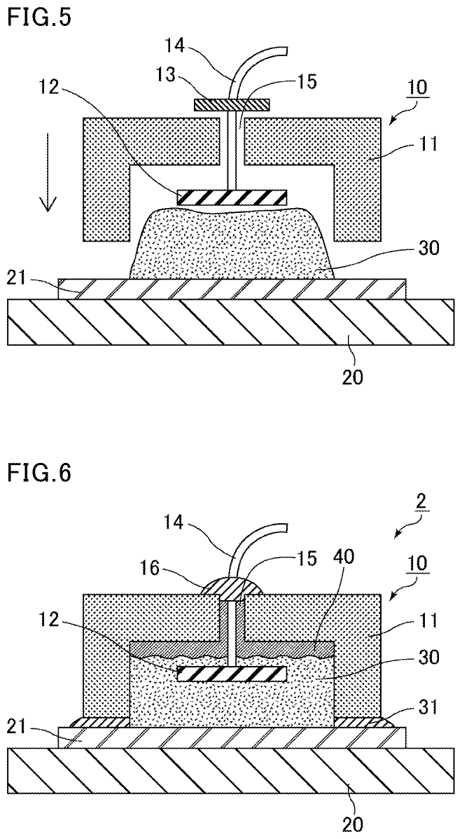

FIG. 5 illustrates one method of applying connector of the present disclosure. FIG. 5 illustrates a connector 10 which is placed over a conductive material 30 positioned on a connecting surface 21. The conductive material 30 is provided in such an amount as to fill a space within the housing 11. The housing 11 is positioned over the conductive material 30 and sealed in place. Further, once in place, the clip 13 may be released such that the connector plate 12 may lower within the housing 11. A seal 16 (See FIG. 3) may further be formed over the housing opening 15. Where the conductive material 30 does not fill the housing 11, the seal 16 may extend into the opening 15 to fill the housing 11. In some further examples, an adhesive may be provided on a bottom surface of the housing 11.

FIG. 6 illustrates a glass product according to an embodiment disclosed herein. A glass product 2 shown in FIG. 6 includes a connector 10 on a glazing 20 having a connecting surface 21 thereon. The housing 11 shown has been filled with a conductive material 30 and a non-conductive material 40. The non-conductive material 40 fills the housing above the conductive material 30. A seal 16 is used to close an opening 15 in the housing 11. In some embodiments, the non-conductive material 40 may act as a seal. The conductive material 30 within the housing 11 is positioned between the connector plate 12 and the connecting surface 21. The connector plate 12 is electrically connected to the underlying connecting surface 21 by the conductive material 30 therebetween. As shown, the housing interior may have no air pockets under the housing seal 16. The seal 16 is formed at a housing opening 15 and may be formed around an extension 14 which may pass through such an opening 15. In some embodiments, the housing opening 15 to be sealed may not include the extension 14 therethrough.

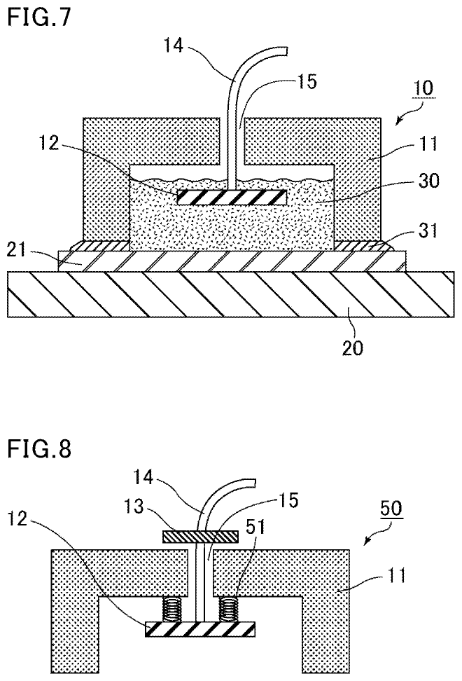

FIG. 7 illustrates a connector on a glazing during a method of applying the connector to the glazing. The housing 11 shown has been filled with a conductive material 30 and the clip 13 (see FIG. 1) removed from the extension 14. A seal 31 is shown on the bottom of the housing 11. The seal 31 may spill out from under the housing 11. In some embodiments, the housing 11 may be sealed in place prior to filling the housing 11 with a conductive material 30.

FIG. 8 illustrates a connector according to some embodiments disclosed herein. FIG. 8 illustrates a connector 50 having a housing 11 and a connector plate 12 within the housing 11. The connector plate 12 includes an extension 14 which extends from the connector plate 12 through an opening 15 in the housing 11. A clip 13 is attached to the extension 14 and holds the connector plate 12 in place in relation to the housing 11. The connector 50 includes at least one spring 51 positioned between the housing 11 and the connector plate 12. The at least one spring 51 is evenly distributed across the connector plate 12. The springs 51 shown may be in a compressed state, held by the extension clip 13. Release of the clip 13 may release the connector plate 12 and the springs 51.

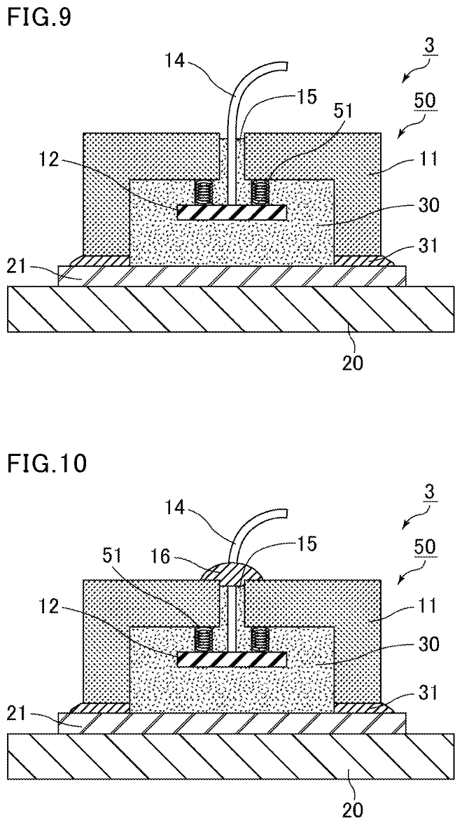

FIG. 9 illustrates a glass product according to an embodiment disclosed herein. A glass product 3 shown in FIG. 9 includes a connector 50 on a glazing 20 having a connecting surface 21 thereon. The housing 11 shown has been filled with a conductive material 30 and the clip 13 (see FIG. 8) removed from the extension 14. A seal 31 is shown at the bottom of the housing 11. The conductive material 30 within the housing 11 is positioned between the connector plate 12 and the connectable material 21. The connector plate 12 is electrically connected to the underlying connectable material 21 by the conductive material 30 therebetween. In some embodiments, the housing 11 may be sealed in place prior to filling the housing 11 with a conductive material 30. The seal 31 may spill out from under the housing 11. The springs 51 may provide pressure against the connector plate 12 which may compress conductive material 30 below the connector plate 12. As shown in FIG. 9, the conductive material 30 may fill the entire housing 11, including below and above the connector plate 12. In some embodiments, the extension 14 may include an insulative coating.

FIG. 10 illustrates a glass product according to an embodiment disclosed herein. FIG. 10 illustrates a connector 50 attached to a glazing 20 wherein the connector housing 11 is sealed closed. As shown, the housing interior may have no air pockets under the housing seal 16. The seal 16 is formed at a housing opening 15 and may be formed around an extension 14 which may pass through such an opening 15.

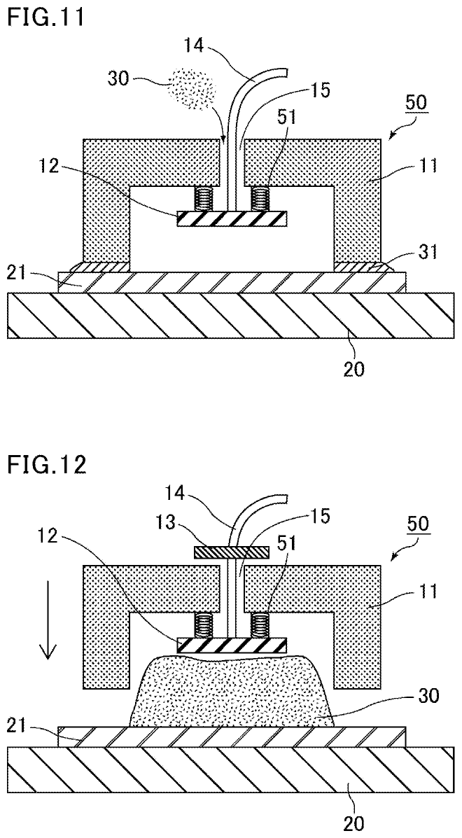

FIG. 11 illustrates one method of applying connector of the present disclosure. A connector 50 having a housing 11, a connector plate 12 within the housing 11 and springs 51 positioned between the housing 11 and the connector plate 12 is placed over a connecting surface 21 on a glazing 20. A conductive material 30 is filled in the housing 11 through an opening 15. A seal 16 (See FIG. 10) may further be formed over the housing opening 15. A bottom edge of the housing 11 may be sealed as well.

FIG. 12 illustrates one method of applying connector of the present disclosure. FIG. 12 illustrates a connector 50 which is placed over a conductive material 30 positioned on a connecting surface 21 as glazing busbar. The conductive material. 30 is provided in such an amount as to fill a space within the housing 11. The housing 11 is positioned over the conductive material 30 and sealed in place. Further, once in place, the clip may be released such that the release the connector plate 12 and the springs 51 are released and the connector plate 12 may lower within the housing 11. Some embodiments may not include a clip 13. A seal 16 (See FIG. 10) may further be formed over the housing opening 15.

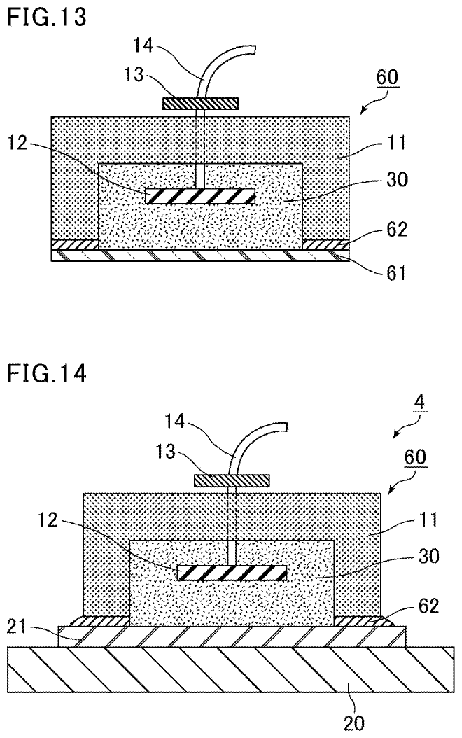

FIG. 13 illustrates a connector according to an embodiment disclosed herein. FIG. 13 illustrates a connector 60 having a housing 11 and a connector plate 12 within the housing 11. The connector plate 12 includes an extension 14 which extends from the connector plate 12 in the housing 11. A clip 13 is attached to the extension. 14 and holds the connector plate 12 in place in relation to the housing 11. Some embodiments may not include a clip 13. A film 61 as liner is placed across a bottom of the housing 11. The film 61 encloses a space within the housing 11. A conductive material 30 is kept within the housing 11 and around a connector plate with a film 61. The film 61, as shown, also covers adhesive 62 on a bottom surface of the housing 11.

FIG. 14 illustrates a glass product according to an embodiment disclosed herein. A glass product 4 shown in FIG. 14 includes a connector 60 positioned on a glazing 20 having a connecting surface 21 thereon. The film 61 (see FIG. 13) is removed from the connector 60 and the connector 60 is placed on the glazing 20. The conductive material 30 within the housing 11 is positioned between the connector plate 12 and the connecting surface 21. The connector plate 12 is electrically connected to the underlying connecting surface 21 by the conductive material 30 therebetween. The conductive material 30 is provided in such an amount as to fill a space within the housing 11. The housing 11 is positioned over the connecting surface 21 and sealed in place by adhesive 62 on the housing 11. Where a clip 13 is used to maintain the placement of a connector plate 12 and extension 14, the clip may be removed when the connector 60 is in place on the glazing 20. The seal 62 may spill out from under the housing 11 in some embodiments.

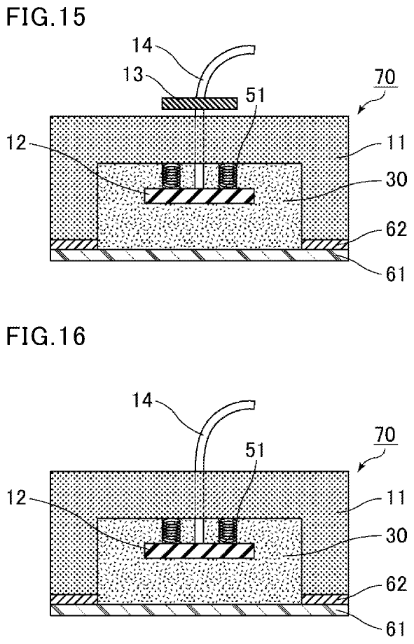

FIG. 15 illustrates a connector according to an embodiment disclosed herein. FIG. 15 illustrates a connector 70 including at least one spring 51 positioned between the housing 11 and the connector plate 12. Prior to applying on a glazing, the conductive material 30 is kept within the housing 11 and around a connector plate 12 with a film 61. The film 61, as shown, also covers adhesive 62 on a bottom surface of the housing 11. In some embodiments, the springs 51 shown may be in a compressed state, held by the extension clip 13.

FIG. 16 illustrates a connector according to an embodiment disclosed herein. As shown in FIG. 16, the connector 70 may not include a clip 13. When applied, the springs 51 may provide pressure against the connector plate 12 which may compress conductive material 30 below the connector plate 12.

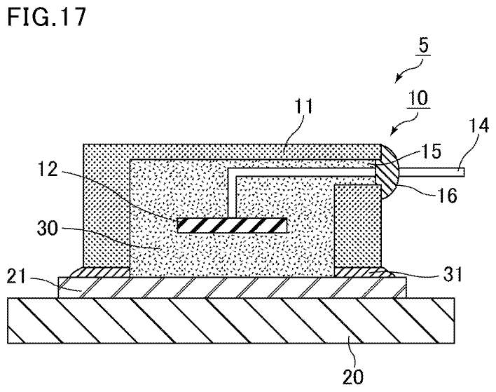

FIG. 17 illustrates a glass product according to an embodiment disclosed herein. A glass product 5 shown in FIG. 17 includes a connector housing 11 having opening at a side face of the housing 11, instead of at the top face of the housing 11. The extension 14 extends from the connector plate 12 through the opening at the side face of the housing 11. The opening at the side face of the housing 11 is sealed closed by seal 16.

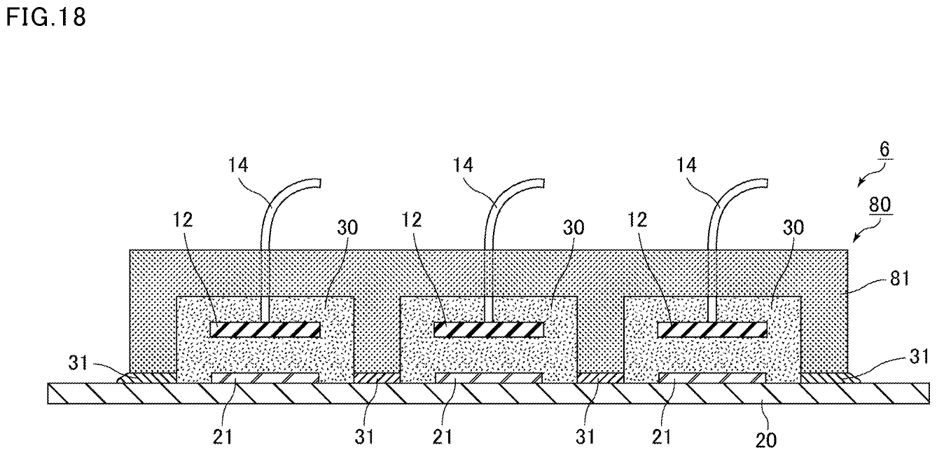

FIG. 18 illustrates a glass product according to an embodiment disclosed herein. A glass product 6 shown in FIG. 18 includes connector 80 on a glazing 20 having a plurality of connecting surfaces 21 thereon. The connector 80 has a multiple-compartment housing 81 having at least two independent compartments. A connector plate 12 is arranged in each compartment of housing 81. Each compartment is filled with a conductive material 30. A seal 31 is shown at an edge of the housing 81 and boundaries between the compartments. The seals 31 and boundaries between compartments are non-conductive so as to keep the compartments electrically isolated from each other. Conductive material 30 within the compartments may not migrate through the seals 31 or barriers. The conductive material 30 within the housing 81 is positioned between the connector plates 12 and the connecting surfaces 21. Each connector plate 12 is electrically connected to an underlying connecting surface 21 by the conductive material 30 therebetween. In some embodiments, connector 80 may include at least one spring positioned between the housing 81 and a connector plate 12.

Particular spatial terms such as “bottom” and “above” are used herein to describe the glass product or the connector in its orientation shown in the drawings and are not intended to be absolute.

The above description of the disclosure is provided to enable a person skilled in the art to make or use the disclosure. Various modifications to the disclosure will be readily apparent to those skilled in the art, and the common principles defined herein may be applied to other variations without departing from the spirit or scope of the disclosure. Further, the above description in connection with the drawings describes examples and does not represent the only examples that may be implemented or that are within the scope of the claims.

Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise. Thus, the disclosure is not to be limited to the examples and designs described herein but is to be accorded the widest scope consistent with the principles and novel features disclosed herein.

1. A glass product, comprising:
a glazing having a connectable material with a connecting surface on the glazing;
a connector including a housing, a connector plate within the housing, and an extension which extends from the connector plate through the housing; and
a conductive material within the housing, wherein at least part of the conductive material is positioned between the connector plate and the connecting surface and the conductive material is in a form of a paste.

2. (canceled)

3. The glass product according to claim 1, further comprising a non-conductive material within the housing.

4. The glass product according to any one of claim 1, wherein the connector includes at least one spring positioned between the housing and the connector plate.

5. The glass product according to claim 4, wherein the at least one spring is evenly distributed across the connector plate.

6. The glass product according to any one of claims 1 to 5, wherein the connector includes an adhesive on a bottom surface of the housing.

7. The glass product according to claim 6, wherein the adhesive is a pressure sensitive adhesive.

8. The glass product according to claim 6, wherein the adhesive is an ultraviolet light curable adhesive.

9-19. (canceled)

20. A method of applying a connector to a glazing, the method comprising:
positioning a conductive material on a connecting surface on the glazing, wherein the conductive material is a paste; and
positioning a connector including a housing and a connector plate within the housing over the conductive material.

21. The method according to claim 20, wherein the housing includes an adhesive on a bottom surface of the housing.

22. The method according to claim 21, wherein the adhesive is a pressure sensitive adhesive.

23. The method according to claim 21, wherein the adhesive is an ultraviolet light curable adhesive.

24. The method according to any one of claim 20, further comprising:
filling the housing with a non-conductive material through an opening in the housing after the positioning the connector over the conductive material.

25. The method according to any one of claim 20, wherein the connector includes at least one spring positioned between the housing and the connector plate.

26. A connector, comprising:
a housing;
a connector plate within the housing;
an extension which extends from the connector plate through the housing;
a conductive material within the housing, wherein the conductive material is in a form of a paste; and
a film across a bottom of the housing, wherein the film encloses a space within the housing.

27. The connector according to claim 26, wherein the extension is a wire connection.

28. The connector according to claim 26, further comprising a clip on the extension, wherein the clip holds the connector plate in place in relation to the housing.

29. The connector according to any one of claim 26, further comprising an adhesive on a bottom surface of the housing, wherein the film across the bottom of the housing covers the adhesive on the bottom surface of the housing.

30. The connector according to claim 29, wherein the adhesive is a pressure sensitive adhesive.

31. The connector according to claim 29, wherein the adhesive is an ultraviolet light curable adhesive.

32. The connector according to any one of claim 26, further comprising at least one spring within the housing, wherein the at least one spring is positioned between the connector plate and the housing.

33-34. (canceled)
